(19) United States
(12) Patent Application Publication
(10) Pub. No.: US 2019/0391495 A1
(43) Pub. Date: Dec. 26, 2019

(54) METHOD OF MAKING A LITHOGRAPHIC PRINTING PLATE PRECURSOR CONTAINING A DIAZONIUM COMPOUND

(71) Applicant: AGFA NV, Mortsel (BE)

(72) Inventors: Peter HENDRIKX, Mortsel (BE); Sam VERBRUGGHE, Mortsel (BE); Hubertus VAN AERT, Mortsel (BE)

(21) Appl. No.: 16/465,267

(22) PCT Filed: Nov. 28, 2017
(86) PCT No.: PCT/EP2017/080691

§ 371 Date: May 30, 2019

(30) Foreign Application Priority Data
Dec. 1, 2016 (EP) 16201734.7

(51) Int. Cl. G03F 7/20; G03F 7/016; G03F 7/32; G03F 7/029; G03F 7/033; G03F 7/032

(52) U.S. Cl. CPC G03F 7/2057; G03F 7/016; G03F 7/0325; G03F 7/029; G03F 7/033; G03F 7/322

(57) ABSTRACT

A method of making a lithographic printing plate includes the steps of (i) image wise exposing a lithographic printing plate precursor with a digitally modulated light source so as to obtain image areas in the exposed parts of the precursor and non-image areas in the non-exposed parts of the precursor, the precursor including a hydrophilic substrate and a photosensitive layer applied onto the substrate, the photosensitive layer including a diazonium compound; and (ii) contacting the exposed precursor with an aqueous solution including a water-soluble hydrophilic polymer and/or surfactant and having a pH between 3 and 9 thereby first removing the photosensitive layer in the non-image areas and depositing the hydrophilic polymer and/or surfactant onto the substrate in the non-image areas of the printing plate precursor.

### CROSS REFERENCE TO RELATED APPLICATIONS

This application is a 371 National Stage Application of PCT/EP2017/080691, filed Nov. 28, 2017. This application claims the benefit of European Application No. 16201734.7, filed Dec. 1, 2016, which is incorporated by reference herein in its entirety.

### BCAKGROUND OF THE INVENTION

### 1. Field of the Invention

The present invention relates to a method and composition for making lithographic printing plates. More particularly, the invention relates to the process of removing non-imaged parts and preserving the non-image areas in one step of a digitally exposed negative-working lithographic printing plate precursor containing a diazonium compound.

### 2. Description of the Related Art

Lithographic printing presses use lithographic printing plates which are mounted on a cylinder of the printing press. The plate carries a lithographic image on its surface and printing is obtained by applying ink to said image and then transferring the ink from the plate onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. The ink is preferentially retained by the oleophilic area, corresponding to the image area, and the water or fountain solution is preferential retained by the hydrophilic area, corresponding to the non-image area.

One of the most common types of lithographic printing plate precursor to which the present invention is directed, has a photosensitive layer containing a diazonium compound applied on a hydrophilic surface, in most cases an aluminium base substrate. The coating may respond to light by having the exposed part become hardened or less soluble so that it is not removed in the developing process, while the non-exposed parts of the layer are removed during the development process. Such a plate is referred to as negative acting. The image area remaining is ink receptive or oleophilic and the non-image area or background is water receptive or hydrophilic. To protect the non-image areas, a hydrophilic polymer or surfactant is applied after the development step and the rinsing step of the plate making processing. The differentiation between image and non-image areas is made in the exposure process. During a long time this was based on the exposure of the image parts of the photosensitive layer to a light source emitting UV radiation through a film. The film was carrying the image to be printed as transparent and non-transparent parts to UV light. The film, carrying the image had to be prepared by means of a separate process including image wise exposure, development, fixing and rinsing. Before exposure of the plate precursor, the film is positioned between the UV light source and the photosensitive layer by means of vacuum to ensure good contact between film and photosensitive layer.

The process step for preparing the film carrying the image to be printed and the exposure of the plate precursor to the light source through the film makes the total image wise exposure process time and limits the achievable plate making throughput, expressed as printing plates produced per hour. To solve this problem, companies such as Luscher AG and Xeikon International B.V. have made exposure units, also called UV setters. These comprise an exposure head carrying an UV light source, in most cases lasers, and directly expose the photo sensitive layer of a negative acting lithographic printing plate precursor containing a diazonium compound (see U.S. Pat. No. 6,211,948 B1 and U.S. Pat. No. 6,411,366 B2). The emitted light from the exposure head is digitally modulated based on the digital image to be printed and no film is to be used anymore to image wise expose the precursor. Modern UV-light plate setters can expose up to 70 plate precursors (8-up format)/h. This has considerably decreased the total time of exposing the precursor. However, due to this increased throughput the processing of the exposed precursor, which comprises a development step, a rinsing step and a gumming step, has become now the speed limiting factor to achieve high plate making throughputs.

GB1515174 discloses a process for simultaneously developing and preserving printing plates. The process is based on an aqueous liquid containing a water-miscible organic solvent which is capable of removing unhardened areas of the photosensitive layer and a minor proportion of a water-soluble colloid which is capable of preserving the non-image parts of the printing plate. To achieve a removal of the non-image parts of the photosensitive layer, the amount of water-miscible solvent in the processing liquid has to be more than 20% by weight. This amount represents considerable environmental and safety issues. Furthermore, according to GB1515174 the solutions further contain inorganic salts as developing assistant and which may crystallize onto processing equipment parts due to evaporation. The removal of the coating in the non-image areas needs mechanical aid and the development time is usually more than 60s.

U.S. Pat. No. 5,035,982A discloses an aqueous developer composition for developing negative working lithographic printing pate precursors without water soluble organic solvents. The composition does not comprise a hydrophilic polymer which is capable of preserving the non-image areas of the plate. WO2005/111727 discloses a method for making a lithographic printing plate whereby a negative-working photopolymer printing plate precursor is image-wise exposed and developed with a gum solution thereby developing and gumming the plate in a single step. Negative-working photopolymer precursors suffer from oxygen inhibition and have therefore an extra top layer which has to be applied via an extra coating and must be removed during the development process. This removal of the extra top layer, mostly consisting of polyvinyl alcohol, causes a strong decrease of the viscosity of the development solution leading to a rapid clogging of tubes, filters and nozzles of the equipment.

Therefore there is a need for a high throughput processing of the exposed precursor processing of diazonium based lithographic printing plate precursors exposed by means of a digitally modulated UV light source using liquids which do not represent safety or environmental issues and provide a constant activity towards removal of non-image parts of the photosensitive layer throughout the plate production.

### SUMMARY OF THE INVENTION

Preferred embodiments of the present invention provide a method of lithographic printing plate making which solves the above stated problems. The method comprises exposure of a negative acting lithographic printing plate precursor containing a diazonium compound by means of a digitally modulated light source followed by a one-step processing.

Preferred embodiments are described below.

Further advantages and embodiments of the present invention will become apparent from the following description.

### DETAILED DESCRIPTION OF THE PREFERRED EMBODIMENTS

### A. Lithographic Printing Plate Precursor

The lithographic printing plate precursor used in the method of the invention comprises a hydrophilic substrate and a photosensitive layer applied onto the substrate.

### A.1. Photosensitive Layer

The photosensitive layer which is applied onto a hydrophilic substrate comprises a diazonium compound and preferably a binder.

### A.1.1. Diazonium Compound

Diazonium compounds most commonly employed in the preparation of light sensitive compositions suitable for the present invention may be characterized by the generic structure A —N₂⁺X⁻, wherein A is an aromatic or heterocyclic residue and X is the anion of an acid. Specific examples of light sensitive diazonium materials useful include higher molecular weight compositions obtained, for example, by the condensation of certain aromatic diazonium salts in an acid condensation medium with active carbonyl compounds such as formaldehyde, as disclosed for example in U.S. Pat. No. 2,063,631 and U.S. Pat. No. 2,667,415. The photosensitive coating usable in the present invention is produced by using condensation products of diazonium salts of p-amino-diphenylamines, such as diphenylamine-4-diazonium chloride or diphenylamine-4-diazonium bromide or diphenyl-arnine-4-diazonium phosphate, with formaldehyde in phosphoric acid of high concentration. The term phosphoric acid also includes pyrophosphoric acid, metaphosphoric acid, and poly-phosphoric acid.

Another preferred class of diazonium compounds is described in U.S. Pat. No. 3,849,392. The compounds are the polycondensation product of 3-methoxy-4-diazo-diphenyl amine sulfate and 4,4′-bis-methoxy methyl-diphenyl ether, preferably precipitated as mesitylene sulfonate, as taught in U.S. Pat. No. 3,849,392. Another preferred diazonium salt is benzenediazonium, 2-methoxy-4-(phenylamino)-, 2,4,6-trimethylbenzenesulfonate (1:1), polymer with 1,1′-oxybis[4-(methoxymethyl)benzene]. The preparation of this diazonium salt is disclosed in DE 2024244A. Other diazonium salts disclosed in this document are suitable to be contained in the photosensitive layer.

The diazonium salt is preferably present in the photosensitive layer in an amount of from about 20% to about 100% by weight with respect to the total weight of the photosensitive layer. A more preferred range is from about 25% to 50% and most preferably from about 30% to 45%.

The diazonium salts used in the precursor of the invention absorb UV light in the region of 360 nm to 420 nm.

### A.1.2. Binder

The binder which may be added to the diazonium compound to improve mechanical resistance of the photosensitive layer such as to increase the run length of the obtained printing plate and to improve the ability to be easily processed in the processing of the liquid of the invention.

Suitable binders are polyvinyl acetates, epoxy resins based on bis-phenol-A-epichlorohydrin, p-(vinyl butyral-co-,vinyl acetate-co-vinyl alcohol), unplasticized urea resin of an approximate acid number of 2 (Resamin 106 F), Recinene-modified alkyd resin, Resins comprising a polyvinyl acetate resin and a styrene/maleic acid half ester copolymer.

The polyvinyl acetate resin useful for the practice of the present invention has a weight average molecular weight in the range of from about 40.000 to less than 800.000. A preferred weight average molecular weight maximum is about 700.000; more preferably 680.000. The most preferred average molecular weight is in the range of about 80.000 to 200,000. Preferred binders are the butyl semi-ester of the maleic acid anhydride/styrene copolymers (such as Scripset® 540, available from Monsanto) and the styrene/maleic acid half ester copolymers as disclosed in U.S. Pat. No. 4,511,640A. More preferred binders are obtained by reacting p-[vinylbutyral-co-vinyl alcohol-co-vinyl acetate] such as Mowital B30T or Mowital B60T (from Kuraray Europe GmbH) with 1. maleic acid anhydride to a half-ester and half acid, with the OH of the polyvinylalcohol as disclosed in Preparation Example 5 in U.S. Pat. No. 5,695,905, or 2. with trimellitic anhydride to a half-ester and half acid such as a binder consisting of 26 mol % vinylalcohol (9.3 wt %), 64 mol % vinylbutyral, 2 mol % vinylacetate and 8 mol % trimellitic ester or 3. with phthalic acid anhydride to a half-ester and half acid such as a binder consisting of 42 mol % vinylalcohol, 3 mol % vinylacetate, 38 mol % vinylbutyral and 17 mol % phthalic ester.

If a binder is used in the photosensitive layer of the invention than the binder is preferably present in the layer in an amount of from about 8% to about 60% by weight with respect to the total weight of the photosensitive layer. A more preferred range is from about 12% to 50% and most preferably from about 18% to 45%.

The weight ratio of binder to diazonium compound does not exceed 20, preferably equal to or less than 10, more preferably between 0.8 and 1.2.

A particular preferred mixture of a diazonium compound with a binder to form a photosensitive layer useful in the invention, is the mixture of the polycondensation product of 3-methoxy-4-diazo-diphenyl amine sulfate and 4,4′-bis-methoxy methyl-diphenyl ether, precipitated as mesitylene sulfonate with the binder obtained by reacting p-[vinylbutyral-co-vinyl alcohol-co-vinyl acetate] such as Mowital B30T maleic acid anhydride to a half-ester and half acid, with the OH of the polyvinylalcohol as disclosed in Preparation Example 5 in U.S. Pat. No. 5,695,905. The weight ratio binder/diazonium compound being preferably from 0.8 to 1.2.

### A.1.3. Additives

The photosensitive layer used in the method according to the invention may further comprise additives.

Suitable acid stabilizers useful within the context of the present invention include phosphoric, citric, tartaric and p-toluene sulfonic acids. The acid stabilizer, when one is used, is preferably present in the coating composition in an amount of from about 1.5% to about 4.5% by weight of the solid composition components. A more preferred range is from about 2.0% to 4.0% and most preferably from about 2.5% to 3.5%.

Exposure indicators useful in conjunction with the present invention include para phenyl azo diphenyl amine, Calcozine Fuchine dyes and Crystal Violet and Methylene Blue dyes. The exposure indicator, when one is used, is preferably present in the coating composition in an amount of from about 0.05% to about 0.35% by weight of the solid composition components. A more preferred range is from about 0.10% to 0.30% and most preferably from about 0.15% to 0.25%.

Non-limiting examples of colorants useful with the photographic element of the present invention include such dyes as Acetosol Fire Red 3GLS, Sandolan Eosin E-G, Acetosol Green BLS, Genacryl Blue 3G, Sandolan Cyanine N-6B, Sandoplast Blue R, Atlantic Alizarine Milling Blue FFR 200, Neozapon Fiery Red BL, Erythrosine, Methylene Blue IaD Extra, Victoria Pure Blue FGA; and such pigments as Geen Gold Pigment and Sunfast Violet.

The colorant, when one is used, is preferably present in the coating composition in an amount of from about 0.25% to about 0.55% by weight of the solid composition components. A more preferred range is from about 0.30% to 0.50% and most preferably from about 0.35% to 0.45%.

Suitable solvents which may be used as a medium to combine the ingredients of the present composition include Methyl Cellosolve, ethylene glycol ethers, butyrolactone, alcohols as ethyl alcohol and n-propanol, and ketones such as methyl ethyl ketone.

The coverage of the photosensitive layer is preferably between 0.1 and 1.2 g/m², more preferably between 0.5 and 0.8 g/m².

### A.2. Hydrophilic Substrate

The lithographic printing plate precursor used in the present invention comprises a substrate which has a hydrophilic surface or which is provided with a hydrophilic layer. The substrate may be a sheet-like material such as a plate or it may be a cylindrical element such as a sleeve which can be slid around a print cylinder of a printing press. Preferably, the substrate is a metal substrate such as aluminium or stainless steel. The substrate can also be a laminate comprising an aluminium foil and a plastic layer, e.g. polyester film.

A particularly preferred lithographic substrate is an electrochemically grained and anodized aluminium substrate. The aluminium substrate has usually a thickness of about 0.1-0.6 mm. However, this thickness can be changed appropriately depending on the size of the printing plate used and/or the size of the plate-setters on which the printing plate precursors are exposed. The aluminium is preferably grained by electrochemical graining, and anodized by means of anodizing techniques employing phosphoric acid or a sulphuric acid/phosphoric acid mixture. Methods of both graining and anodization of aluminium are very well known in the art.

By graining (or roughening) the aluminium substrate, both the adhesion of the printing image and the wetting characteristics of the non-image areas are improved. By varying the type and/or concentration of the electrolyte and the applied voltage in the graining step, different type of grains can be obtained. The surface roughness is often expressed as arithmetical mean centre-line roughness Ra (ISO 4287/1 or DIN 4762) and may vary between 0.05 and 1.5 μm. The aluminium substrate of the current invention has preferably a Ra value below 0.80 μm, more preferably below 0.65 μm, even more preferably below 0.60 μm and most preferably below 0.50 μm. The lower limit of the Ra value is preferably about 0.1 μm. More details concerning the preferred Ra values of the surface of the grained and anodized aluminium substrate are described in EP 1 356 926.

By anodising the aluminium substrate, its abrasion resistance and hydrophilic nature are improved. The microstructure as well as the thickness of the Al₂O₃ layer, are determined by the anodising step, the anodic weight (g/m² Al₂O₃ formed on the aluminium surface) varies between 1 and 8 g/m². The anodic weight is preferably 2 g/m², more preferably 2.5 g/m² and most preferably 3.5 g/m².

The grained and anodized aluminium substrate may be subject to a so-called post-anodic treatment to improve the hydrophilic properties of its surface. For example, the aluminium substrate may be silicated by treating its surface with a sodium silicate solution at elevated temperature, e.g. 95° C. Alternatively, a phosphate treatment may be applied which involves treating the aluminium oxide surface with a phosphate solution that may further contain an inorganic fluoride. Further, the aluminium oxide surface may be rinsed with a citric acid or citrate solution. This treatment may be carried out at room temperature or may be carried out at a slightly elevated temperature of about 30 to 50° C. A further interesting treatment involves rinsing the aluminium oxide surface with a bicarbonate solution. Still further, the aluminium oxide surface may be treated with polyvinylphosphonic acid, polyvinylmethylphosphonic acid, phosphoric acid esters of polyvinyl alcohol, polyvinylsulphonic acid, polyvinylbenzenesulphonic acid, sulphuric acid esters of polyvinyl alcohol, and acetals of polyvinyl alcohols formed by reaction with a sulphonated aliphatic aldehyde. It is further evident that one or more of these post-treatments may be carried out alone or in combination. More detailed descriptions of these treatments are given in GB-A 1 084 070, DE-A 4 423 140, DE-A 4 417 907, EP-A 659 909, EP-A 537 633, DE-A 4 001 466, EP-A 292 801, EP-A 291 760 and U.S. Pat. No. 4,458,005.

The substrate can also be a flexible substrate, which may be provided with a hydrophilic layer, hereinafter called ‘base layer’. The flexible substrate is e.g. paper, plastic film or aluminium. Preferred examples of plastic film are polyethylene terephthalate film, polyethylene naphthalate film, cellulose acetate film, polystyrene film, polycarbonate film, etc. The plastic film substrate may be opaque or transparent.

### B. Image Wise Exposure Via a Digitally Modulated Light Source.

The method of the invention comprises the image wise exposure of the photosensitive layer of the precursor. The photosensitive layer as described above is sensitive in the UV-region and the short wavelength region of the visible light spectrum. Therefore, the light source should at least emit light having a wavelength between 360 and 420 nm. The light source is built in an exposure head. Different modes can be used to expose the lithographic printing plate precursor, one where the plate is immobile and the exposure head moves back and forth such is in image setters having an internal drum, one where the plate is mounted onto a drum which rotates at high speed while the exposure head moves from one side of the drum to the other side of the drum.

The light source can be a bulb or lamp such as mercury vapour bulbs. Preferably lasers are used due to the high energy density achievable, such as fibre-coupled laser diodes emitting at 405 nm. This high energy density makes it possible to achieve high plate throughput during the exposure step. The image wise exposure via a laser is done by digital modulation of the current and or voltage.

The image wise exposure may be achieved by means of modulation of the light emitted from the light source. This modulation can be done by means of digital mirror devices, also called DMD imaging. UV setters which are suitable to digitally modulate the light source such as to image wise expose a diazonium compound containing printing plate precursor are available from Luscher AG and Basysprint from Xeikon International B.V. The digital information is obtained from a digital image which is made available to the UV setter.

### C. Aqueous Solution for Contacting the Exposed Plate Precursor.

The exposed lithographic printing plate precursor is contacted with an aqueous solution comprising a water-soluble hydrophilic polymer and/or surfactant and having a pH between 3 and 9 and which removes the photosensitive layer in the non-image areas and deposits the hydrophilic polymer and/or surfactant onto the substrate in the non-image areas of the printing plate precursor. The step wherein the non-exposed parts of the photosensitive layer are removed and the hydrophilic polymer and/or surfactant are deposited onto the substrate in the non-image areas of the printing plate precursor is hereafter named the processing and the aqueous solution suitable for this is named hereafter the processing liquid.

The processing liquid comprises one or more surface protective compounds that are capable of protecting the lithographic image of a printing plate against contamination, e.g. by oxidation, fingerprints, fats, oils or dust, or damaging, e.g. by scratches during handling of the plate. Suitable examples of such compounds are film-forming hydrophilic polymers or surfactants. The layer that remains on the plate after treatment with the processing liquid preferably comprises between 0.05 and 20 g/m² of the surface protective compound.

Preferred polymers for use as protective compound in the processing liquid are gum arabic, pullulan, dextrin, cellulose derivatives such as carboxymethylcellulose, carboxyethylcellulose or methylcellulose, (cyclo)dextrin, poly(vinyl alcohol), poly(vinyl pyrrolidone), polysaccharide, homo- and copolymers of acrylic acid, methacrylic acid or acrylamide, a copolymer of vinyl methyl ether and maleic anhydride, a copolymer of vinyl acetate and maleic anhydride or a copolymer of styrene and maleic anhydride. Highly preferred polymers are homo- or copolymers of monomers containing carboxylic, sulfonic or phosphonic groups or the salts thereof, e.g. (meth)acrylic acid, vinyl acetate, styrene sulfonic acid, vinyl sulfonic acid, vinyl phosphonic acid or acrylamidopropane sulfonic acid.

Examples of surfactants for use as surface protective agent include anionic, zwitterionic and/or non-ionic surfactants. The processing liquid may also comprise one or more of the above hydrophilic polymers as surface protective agent and, in addition, one or more surfactants to improve the surface properties of the coated layer. The surface tension of the processing liquid is preferably from 20 to 60 mN/m.

It has been found after extensive research that the removal of the non-exposed parts of the photosensitive layer comprises two separate steps. A first step wherein photosensitive layer particles are detached from the substrate, followed by a second step wherein these particles are solubilised to obtain a homogeneous solution of the photosensitive layer compounds. If the first step is too slow, no complete removal of the layer in the non-image parts will be obtained, leading to toning on the press in the non-image areas. If the second step is too slow, the removed coating particles will aggregate into larger particles and will deposit on the image and/or non-image areas of the plate, the rollers in the processing machine or other machine parts of the processing equipment. The kinetics of both steps have to be carefully adjusted with respect to each other in order to provide a fast removal without re-deposition of photosensitive layer parts during the one-step processing of the exposed plate precursor.

The solution may therefore contain a first surfactant to assist in the detachment from the substrate of the non-exposed portions of the coating. The first surfactant is preferably an anionic surfactant, and more preferably includes one or more components selected from the group consisting of sodium, lithium, potassium, magnesium or calcium octyl, decyl or dodecyl sulfate. The most preferred ingredient is sodium octyl sulfate. The first surfactant is also useful in the development process by imparting low surface tension so that the components of the processing liquid may penetrate the non-exposed portions of the photosensitive layer and facilitate their removal. This component may be present in the processing liquid composition in an amount of from about 0.5% to about 10.0%, preferably from about 0.5% to about 2.0% based on the weight of the developer composition.

The solution may contain a second surfactant to facilitate the dispersion of the removed coating particles and prevent them from aggregating into larger particles and/or prevent them from being deposited on the image or non-image areas of the plate, the rollers in the processing equipment or other machine parts. The second surfactant can be an anionic surfactant such as sodium, lithium or potassium salt of sulfonic acid. Suitable examples are hydroxy-alkanesulfonates, alkanesulfonates, straight-chain alkylbenzenesulfonates, branched alkylbenzenesulfonates, diphenyl ether sulfonates, alkylnaphthalenesulfonates, alkylphenoxypolyoxyethylenepropylsulfonates, petroleum sulfonates.

Specific examples include sodium dodecylphenoxybenzene disulfonate, the sodium salt of alkylated naphthalenesulfonate, disodium methylene-dinaphtalene-disulfonate, sodium dodecyl-benzenesulfonate, sulfonated alkyl-diphenyloxide, ammonium or potassium perfluoroalkylsulfonate. The alkyl benzene sulfonates are preferred. Particularly preferred among these sulfonates is dodecylbenzensulfonate.

The second surfactant may also be a non-ionic surfactant. Suitable examples of the non-ionic surfactants include polyoxyethylene alkyl ethers, polyoxyethylene alkyl phenyl ethers, polyoxyethylene polystyryl phenyl ethers, polyoxyethylene polyoxypropylene alkyl ethers, polyoxyethylene polyoxypropylene block polymers, partial esters of glycerinaliphatic acids, partial esters of sorbitanaliphatic acid, partial esters of pentaerythritolaliphatic acid, propyleneglycolmonoaliphatic esters, partial esters of sucrosealiphatic acids, partial esters of polyoxyethylenesorbitanaliphatic acid, partial esters of polyoxyethylenesorbitolaliphatic acids, polyethyleneglycolaliphatic esters, partial esters of poly-glycerinaliphatic acids, polyoxyethylenated castor oils, partial esters of polyoxyethyleneglycerinaliphatic acids, aliphatic diethanolamides, N,N-bis-2-hydroxyalkylamines, polyoxyethylene alkylamines, triethanolaminealiphatic esters, and trialkylamine oxides.

Particularly preferred among these non-ionic surfactants are non-ionic surfactants which behave as hydrotropic and have co-solvent properties. Particularly suitable hydrotropic compounds are aryl alkoxylates according to Formula I:

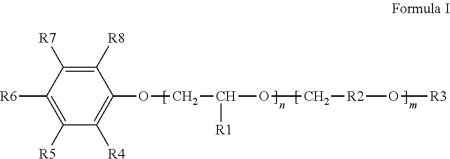

Wherein R1 is a C1-C4 alkyl or an aryl, R2 is a linking group consisting of CH₂ or CH₂—CH(OH) or CH(CH₂OH), R3 is a H or a C1-C4 alkyl, R4 is a H, a C1-C4 alkyl, a (C1-C4 alkyl)aryl or an aryl, R5 is a H, a C1-C4 alkyl, a (C1-C4 alkyl)aryl or an aryl, R6 is a H, a C1-C4 alkyl, a (C1-C4 alkyl)aryl or an aryl, R7 is a H, a C1-C4 alkyl, a (C1-C4 alkyl)aryl or an aryl, and R8 is H, C1-C4 alkyl, a (C1-C4 alkyl)aryl or an aryl. n has a value from 0 to 6 and m has a value from 3 to 16.

The repeating unit with the R1 substituent in Formula I is regarded as the hydrophobic alkoxylate repeating unit, in which the monomer units are formed e.g. by reacting propylene oxide, 1,2-butylene oxide or styrene oxide. The value of n is the average degree of polymerisation of all alkylene oxide units more hydrophobic as compared to ethylene oxide. The repeating unit with the R2 substituent in Formula I is regarded as the hydrophilic alkoxylate repeating unit, in which the monomer units are e.g. based on ethylene oxide or glycidol. The value of m is the average degree of polymerisation of all alkylene oxide units consisting of ethylene oxide or more hydrophilic alkylene oxide units.

The aryl alkoxylate can be a mono-aryl alkoxylate, a bisaryl alkoxylate or a multi-aryl alkoxylate. In a mono aryl alkoxylate, R1 is a C1-C4 alkyl or an aryl, R2 is a linking group consisting of CH₂ or CH₂—CH(OH) or CH(CH₂OH), R3 is a H or a C1-C4 alkyl, R4 is a H or a C1-C4 alkyl, R5 is a H or a C1-C4 alkyl, R6 is a H or a C1-C4 alkyl, R7 is a H or a C1-C4 alkyl and R8 is H or a C1-C4 alkyl.

For monoaryl alkoxylates, n is preferably 0 to 3 and m is preferably 3 to 10, more preferably m is 3 to 5. A preferred aryl alkoxylate is the monoaryl ethoxylate Lansurf P4, which has the formula II:

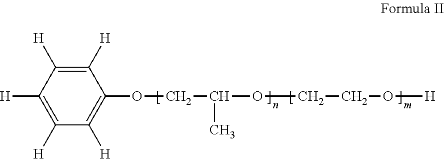

wherein n=0 and m=4, corresponding to CAS registry number 9004-78-8. Other suitable aryl alkoxylates, are CAS registry number 60831-68-7, ie. ethylene oxide-propylene oxide copolymer monophenyl ether or CAS registry number 166582-89-4, ie. Oxirane, polymer with methyloxirane, monophenyl ether, block. Another example of a monoaryl alkoxylate is an alkyl aryl ethoxylate having a short alkyl group, e.g according to Formula I wherein R4 is CH₃, R5=R6=R7=R8 is H, R2 is CH₂, R3 is H and n=0, ie. CAS registry number: 37281-57-5, ie. polyethylene glycol monocresyl ether.

In case of bisaryl alkoxylates, suitable example are ethoxylated 4-hydroxydiphenyls according to Formula III:

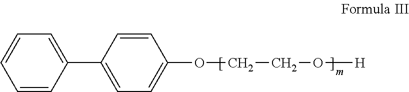

wherein m is preferably between 4 and 16, more preferably between 6 and 10.

Besides mono-aryl alkoxylates and bisaryl alkoxylates, one can also use multi-aryl alkoxylates. The multi-aryl alkoxylate have more than 2 aryl groups outside the alkylene oxide chain(s). Suitable examples are tristeryl ethoxylates according to Formula IV wherein m is preferably between 6 and 16, more preferably between 6 and 12. A more suitable example of a multi aryl alkoxylate is tristyryl ethoxylate having CAS registry number 70559-25-0.

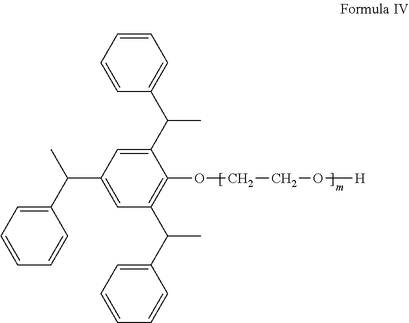

Aryl alkoxylates with more than one ethoxylate chain are also suitable as a second surfactant according to the invention. A suitable example of a mono-aryl alkoxylate having 2 alkoxylate chains is ethoxylated hydroquinone, having CAS registry number 41675-76-7.

A suitable example of a bisaryl alkoxylate is ethoxylated bisphenol acetone according to formula V:

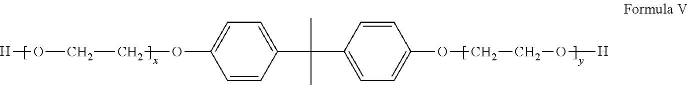

In the preferred structure of a bisphenol ethoxylate according to structure V, one needs to consider the total degree of alkoxylation x+y=m as shown in structure V. Useful examples are bisphenol A derivatives, are Bisphenol A bis(polyethylene-propylene glycol) ether—CAS registry number 65324-64-3, Ethylene oxide-propylene oxide block copolymer ether with bisphenol A—CAS registry number 110120-33-7, Bisphenol A-ethylene oxide-propylene oxide copolymer—CAS registry number 52367-02-9, Bisphenol A-ethylene oxide copolymer—CAS registry number 29086-67-7. The preferred degree of polymerization for the hydrophilic alkylene oxide units (i.e ethylene oxide or more hydrophilic alkylene oxides) in the bisaryl alkoxylated m, is preferably between 6 and 16.

Examples of a multi-aryl alkoxylates having more than one alkoxylate chain are ethoxylated 1,1,2,2-Tetrakis(p-hydroxyphenyl)ethane according to formula VI:

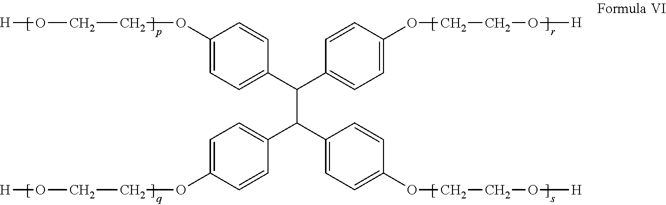

wherein p+q+r+s=m and m is preferably between 6 and 16, more preferably between 6 and 12.

A preferred combination of a non-ionic surfactant and an anionic surfactant is aryl alkoxylated with a salt of sulfonic acid. The second surfactant concentration ranges from about 0.1% to about 11%, more preferably from about 0.5% to about 8% and most preferably from about 0.7% to about 6% by weight. Preferably, the amount of the salt of the sulfonic acid is from 0.1% to 2.0% by weight with respect to the total weight of the aqueous solution.

Two or more of the above surfactants may be used in combination. For example, a combination of two or more different anionic surfactants or a combination of a sulfonate anionic surfactant and a non-ionic surfactant may be preferred.

The solubilisation of the compounds of the photosensitive layer during its removal may also be assisted by means of water soluble organic solvents. Preferably, high boiling solvents with a low vapor pressure (less than 1.0 mm Hg) may be used. The organic solvent is also preferably one that is biodegradable. Suitable organic solvents are glycols, glycol ethers such as tri propylene glycol monobutyl ether and glycol esters. Preferred solvents include but are not restricted to butyrolactone, phenoxy propanol, phenoxy ethanol, benzyl alcohol, methyl pyrrolidone and the like. Most preferred are benzyl alcohol and phenoxyethanol. The preferred concentration of the organic solvent ranges from about 0.5% to about 20%, more preferably from about 0.5% to about 10% and most preferably from about 0.5% to about 5% by weight. From these alcohols, the one with a boiling point above 150° C., preferably above 200° C. are preferred because their activity in the processing liquid is not decreased due to evaporation during the printing plate production.

The water soluble organic solvent may be combined with one of the above mentioned surfactants. In particular, the combination of the water soluble organic solvent with a sulfate surfactant, a sulfonate surfactant and a non-ionic surfactant is preferred.

The combination of the water soluble organic solvent with a sulfonate surfactant, a sulfonate surfactant and a non-ionic surfactant in the processing liquid is particularly preferred because a very good removal of the non-image parts of the precursor, also called clean-out, is still obtained in the processing liquid after the processing of a large amount of printing plate precursors. The combination guarantees a good solubility of plate components, even if the processing solution is loaded with a large amount of plate components after processing of a large amount of plate precursors. In the one step process of the invention, the processing liquid is preferably re-used many times in a closed loop (see below) and assures a good clean out, giving no toning on the press in non-image areas and no deposition of plate components during the whole lifetime of the processing liquid. Values of lifetimes up to 40 m² of plate precursors/ litre of processing liquid can be easily achieved.

The use of low boiling water soluble organic solvents in the processing liquid of the invention should be preferably avoided in this type of processing because due to the multiple re-use of the liquid, these solvents disappear from the liquid and the solubilising power of removed photosensitive layer particles would rapidly decrease in function of time leading to a poor clean out and/or deposition on parts of processing equipment. The rapid evaporation of the volatile organic solvents would further increase the viscosity which would adversely impact the functioning of pumps and spray nozzles or even clog them. The same holds for inorganic salts, which would, due to the important evaporation in a closed loop processing, rapidly crystallize and deposit on the plate precursor or parts of the processing equipment.

According to the present invention the processing liquid has a pH-value preferably between 3 and 9, more preferably between 4.5 and 8.5, most preferably between 6 and 8. The pH of the solution is usually adjusted with a mineral acid, an organic acid, an inorganic base or organic base in an amount of from 0.01 to 2 wt. %. Examples of the mineral acids include nitric acid, sulfuric acid, phosphoric acid and metaphosphoric acid. Especially organic acids are used as pH control agents and as desensitizing agents of the non-image areas. Examples of the organic acids include carboxylic acids, sulfonic acids, phosphonic acids or salts thereof, e.g. succinates, phosphates, phosphonates, sulfates and sulfonates. Specific examples of the organic acid include citric acid, acetic acid, oxalic acid, malonic acid, p-toluenesulfonic acid, tartaric acid, malic acid, lactic acid, levulinic acid, phytic acid and organic phosphonic acid and salts thereof. Preferable organic bases are alkali metal hydroxides and tri ethanol amine.

Further, a chelate compound may be present in the processing liquid. Calcium ions and other impurities contained in the diluting water can have adverse effects on printing and thus cause the contamination of printed matter. This problem can be eliminated by adding a chelate compound to the diluting water. Preferred examples of such a chelate compound include organic phosphonic acids or phosphonoalkanetricarboxylic acids. Specific examples are potassium or sodium salts of ethylenediaminetetraacetic acid, diethylenetriaminepentaacetic acid, triethylenetetraminehexaacetic acid, hydroxyethylethylenediaminetriacetic acid, nitrilotriacetic acid, 1-hydroxyethane-1,1-diphosphonic acid and aminotri(methylenephosphonic acid). Besides these sodium or potassium salts of these chelating agents, organic amine salts are useful. The preferred amount of such a chelating agent to be added is from 0.001 to 1.0 wt. % relative to the processing liquid in diluted form.

Further, an antiseptic and an anti-foaming agent may be present in the processing liquid. Examples of such an antiseptic include phenol, derivatives thereof, formalin, imidazole derivatives, sodium dehydroacetate, 4-isothiazoline-3-one derivatives, benzoisothiazoline-3-one, benztriazole derivatives, amidineguanidine derivatives, quaternary ammonium salts, pyridine derivatives, quinoline derivatives, guanidine derivatives, diazine, triazole derivatives, oxazole and oxazine derivatives. The preferred amount of such an antiseptic to be added is such that it can exert a stable effect on bacteria, fungi, yeast or the like. Though depending on the kind of bacteria, fungi and yeast, it is preferably from 0.01 to 4 wt. % relative to the processing liquid in diluted form. Further, preferably, two or more antiseptics may be used in combination to exert an aseptic effect on various fungi and bacteria. The anti-foaming agent is preferably a surface-active silicone type agent. Among these anti-foaming agents, either an emulsion dispersion type or solubilised type anti-foaming agent may be used. The proper amount of such an anti-foaming agent to be added is from 0.001 to 1.0 wt. % relative to the processing liquid in diluted form.

### D. Method of Processing the Exposed Plate Precursor.

D.1. Contacting the Exposed Plate Precursor with the Processing Liquid

The contacting of the exposed plate precursor with the processing liquid can be done by dipping or rinsing with the processing liquid, both optionally boosted with a mechanical treatment such as rubbing with an impregnated pad or by means of brushes. Preferably the contacting is done in an automatic processing equipment.

The automatic processing equipment comprises at least one processing unit wherein the processing liquid is applied to the precursor by spraying, rinsing, jetting, dipping or coating.

At least one of the processing units may be provided with at least one roller for rubbing and/or brushing the coating while applying the processing liquid to the photosensitive layer. In a preferred embodiment, a row of spray nozzles is located adjacent to one or two brushes or rollers so that a part of the processing liquid is sprayed onto the rollers covered with a molton or bristles of the brushes. The brushes or rollers covered with a molton preferably rotate counter to the direction of movement of the plate precursor or move to and fro to facilitate the removal of the non-image part of the photosensitive layer. In another embodiment, the processing liquid is directly sprayed onto the photosensitive layer of the plate precursor before brushes or rollers facilitate the removal of the non-image part of the photosensitive layer.

The use of a one step processing method thereby removing the non-image parts of the photosensitive layer and preserving the substrate of the non-image parts of the printing plate makes it possible to shorten considerably the processing time of the exposed plate precursor and hence increase the processing throughput. In conventional processing of digitally exposed diazonium containing plate, the process comprises at least three steps: a) a development step wherein the non-image parts of the photosensitive layer are removed and which is taking place in a alkaline based developer; b) a rinsing step to remove all components of the developer including alkali and insoluble coating components; c) a gumming step wherein a hydrophilic polymer or surfactant is deposited onto the substrate of the precursor in the non-image parts to preserve these parts. Due to the presence of all these steps requiring a separate processing unit, the automatic processing equipment has to be made longer in the direction of the plate transport than a processing equipment with only one processing unit. Hence the floor space is decreasing, but more importantly, the processing time of the exposed plate is considerably decreased. In Table 1, lengths of typical state of the art automatic processing equipments are shown and the time required to process the printing plate when the throughput of the UV setter is set at its maximum: 70 plates/h for a 8-up printing plate format.

TABLE 1

| | Nr. of | | Time of |
|---|---|---|---|
| | processing | Length | processing |
| Processor Type | units | (mm) | (s) |
| Agfa Elantrix | 3 | 1300 | 49 |
| DX | | | |
| Agfa Elantrix | 3 | 1250 | 47 |
| SX 95 | | | |
| Agfa Azura C 95 | 1 | 700 | 26 |

The difference in time of processing between conventional processing and the one step processing according to the invention amounts to 20 seconds or more for one printing plate or one set of printing plates suitable for one print run. This time saved can substantially increase the productivity of the printing plate making site.

The use of a single step processing method thereby removing the non-image parts of the photosensitive layer and preserving the substrate of the non-image parts of the printing plate has the further advantage that no rinsing water is required in the plate making process. Not only the consumption of pure water is thereby avoided, but also no provisions have to be taken to collect and handle the rinsing water after use.

The processing liquid used in the single step processing can be collected in a tank and the processing liquid can be used several times (closed loop processing). The processing liquid can also be replenished by adding a replenishing solution to the tank of the processing unit. In an alternative way, the processing liquid may be used once-only, i.e. only starting processing liquid is applied to the coating by preferably a spraying or jetting technique. Said starting processing liquid is a processing liquid which has not been used before for processing a precursor and has the same composition as the processing liquid used at the start of the processing. The starting processing liquid may also be prepared by diluting a concentrated processing liquid, hence a processing liquid wherein a part of the water has been removed. The dilution with water of the concentrated processing liquid can take place manually or automatically in a mixing unit. The mixing unit can be part of the processing equipment.

Said replenishing solution is a solution which may be selected from a starting processing liquid, a concentrated processing liquid solution, a diluted processing liquid, a solution of one or more of the surfactants as described above, water or a solution of a buffer having a pH ranging between 3 and 9. A concentrated or diluted processing liquid is a solution comprising a higher respectively lower concentration of additives of the processing liquid as defined above. A concentrated processing liquid can be added as replenishing solution when the concentration of active products is under a desired level in the processing liquid. A diluted processing liquid or water can be used when the concentration of active products is above a desired level in the processing liquid or when the viscosity of the processing liquid is increased or when the volume of the gum solution is under a desired level, e.g. due to evaporation of the water soluble organic solvent or water.

A solution of one or more surfactants such as a non-ionic surfactant, a sulfate surfactant, a sulfonate surfactant, a water soluble organic solvent as described above or a solution of a buffer can be added when the gum solution needs a higher concentration of a surfactant or organic solvent, or when the pH of the gum solution needs to be controlled at a desired pH value or at a desired pH value in a range of two pH values, e.g. between 6 and 8.

The addition of replenishing solution, i.e. the type and the amount of replenishing solution, may be regulated by the measurement of at least one of the following parameters such as the number and area of plate precursor processed, the time period of processing, the volume in each processing unit (minimum and maximum level), the viscosity (or viscosity increase) of the processing liquid, the pH (or pH change) of the processing liquid, the density (or density increase) of the processing liquid and the conductivity (or conductivity increase) of the processing liquid, or a combination of at least two of them. The density (or density increase) of the processing liquid can be measured with a PAAR density-meter.

The processing liquid according to the method of the invention has preferably a temperature ranging between 15° C. and 85° C., more preferably between 18° C. and 65° C., most preferably between 20° C. and 55° C.

In a preferred embodiment of the present invention, the processing equipment comprises a first and a second processing unit whereby the plate precursor is firstly processed in the first processing unit and subsequently processed in the second processing unit. The precursor may be firstly processed in the first unit with processing liquid which has been used in the second unit, and, subsequently, processed in the unit with starting processing liquid by preferably a spraying or jetting technique. In an alternative way, the first and second processing unit preferably have the configuration of a cascade system, whereby the processing solution used for developing the precursor in the first and second processing unit are respectively present in a first and a second tank, and whereby the processing liquid of the second tank overflows to the first tank when replenishing solution is added in the second processing unit. Optionally, also to the first processing unit a replenishing solution can be added and this replenishing solution may be the same or another replenishing solution than added to the second processing unit, e.g. a diluted processing liquid, a solution of a non-ionic surfactant or water can be added as replenisher to the first processing unit.

In another embodiment of the present invention, the processing equipment comprises a first, a second and a third processing unit whereby the precursor is firstly developed in the first processing unit, subsequently in the second processing unit and finally in the third processing unit. The precursor may be firstly developed in the first processing unit with processing liquid which has been used in the second processing unit, subsequently developed in the second processing unit with processing liquid which has been used in the third processing unit, and finally developed in the third processing unit with starting processing liquid by preferably spraying, jetting or applying via an application roller. In an alternative way, the first, second and third processing unit preferably have the configuration of a cascade system, whereby the processing liquid used for developing the precursor in the first, second and third processing unit are respectively present in a first, a second and a third tank, and whereby the processing liquid of the third tank overflows to the second tank when replenishing solution is added in the third processing unit, and whereby the processing liquid of the second tank overflows to the first tank. Optionally, also to the second and/or first processing unit(s) a replenishing solution may be added and this replenishing solution may be the same or another replenishing solution than added to the third processing unit, e.g. a diluted processing liquid, a solution of a non-ionic surfactant or water can be added as replenisher to the second or first processing unit. In another option, two different replenishing solutions can also be added to one processing unit, e.g. a starting processing liquid and water.

After the contacting of the exposed printing plate precursor with the processing liquid wherein the non-image parts of the photosensitive layer are removed and preserved, the obtained plate can be contacted with a gum solution, also called desensitizing finisher, to further preserve or desensitize the non-image layers or to apply a gum solution which is designed to preserve the non-image parts during a baking step of the plate precursor. Typically, this gum solution is applied via an application roller in a processing unit making part of the processing equipment.

### D.2. Drying of the Printing Plate

After the processing step(s), the obtained lithographic printing plate can be dried in a drying unit. The plate can be dried by heating the plate in the drying unit which may contain at least one heating element selected from a near-IR-lamp, an UV-lamp or a heated metal roller. The plate can also be dried with heated air as known in the drying section of a classical developing machine.

### EXAMPLES

### 1. Materials

All materials used in the following examples were readily available from standard sources such as Sigma-Aldrich (Belgium) and Acros (Belgium) unless otherwise specified. The water used was demineralised water.
Phosphorous acid: solution of 85 (wt) % of phosphorous acid in water
Aluva N: diazonium containing lithographic printing plate precursor from Agfa Graphics N.V.
Malto dextrin: malto dextrin MD14 from AVEBE U.A.-Veendam-NL
TEA: solution of 80 (wt.) % in water of Triethanol amine from Univar Belgium NV
Sagtex: Sagtex DSA from Momentive
Texapon 842: aqueous 42 wt. % solution of an octyl sulphate surfactant from BASF SE
Marlon A365: aqueous 65 wt. % solution of an alkylbenzenesulfonate surfactant from Sasol
Dowanol TPnB: Tri propylene glycol monobutyl ether from Dow Chemical
Emulsogen: Tristerylphenol ethoxylate with 16 EO, available as Emulson AG 7717/A from Lamberti (Italy)
Lansurf P4: phenolic ethoxylate with 4EO, a hydrotropic compound from Lankem
Promex BMK: isothiazolin-3-one biocide, available as Promex BMK 5050A from Prom Chem Ltd-Edenbridge-UK
Promex CMT 14: Biocide available as PROMEX CMT14 from

Proms Kemiske Fabrik Ltd.
Printing ink: K+E Novavit 800 from Skinnex from Flint Group Germany GmbH
Fountain: FS303SF 4%+8% IPA
Paper: Maco 90 g/m²

### 2. Processing Liquid

The processing liquid PL-1 is an aqueous solution and prepared by adding the compounds as listed in Table 2:

TABLE 2

| Compound | Amount (in g) |
|---|---|
| Malto dextrin | 37.50 |
| Phosphorous acid | 3.01 |
| TEA | 12.3 |
| Sagtex | 0.10 |
| Texapon 842 | 10.72 |
| Marlon A365 | 7.48 |
| Dowanol TPnB | 10.0 |
| Emulsogen | 17.5 |
| Benzylalcohol | 10.0 |
| Lansurf P4 | 30.0 |
| Promex BMK | 10.1 |
| Promex CMT 14 | 0.10 |
| Demineralized | Up to 1 litre |
| water | |

After adding demineralised water up to 1 litre, the pH was adjusted with TEA to a value of 7.60.

### 3. UV Exposure of the Diazonium Containing Plate

Two Aluva N plates (900×400 mm) were exposed on a Luscher X POSE 230 internal drum plate setter with a fixed spinner speed of 380 rpm. The right exposure was determined by imaging a digital step wedge with a power series from 69 to 105 mW. A right exposure was considered obtained when the second solid step of the step wedge is fully covered. This condition is respected in reality when the density found on the third solid step of the step wedge was not less than 90% of total density found on a fully covered solid area (100%).

After the exposure, one plate precursor was processed in an EN232 developer (Agfa) at 25° C. and 15 seconds of dwell time in an Elantrix H125 processor (Agfa), rinsed in the water rinsing section and gummed in the gumming section filled with RC795 (Agfa). The second exposed plate precursor was processed in an Azura C95 (Agfa) processing unit comprising only one processing unit and filled with the processing liquid PL-1. The transport speed of the plate was 60 cm/min and the temperature of the processing liquid was 22° C.

After processing and drying, it was observed that both printing plates had a comparable sensitivity to the UV exposure as they showed an equal right exposure of 64 mJ/cm² as determined according to the method above.

### 4. Printing Tests

The obtained printing plates were mounted onto a GT052 Printmaster press (Heidelberg) using the ink, fountain and paper as listed above (see §1). No toning in the non-image areas was observed when prints on paper were made with both printing plates.

5. Printing Tests with Printing Plates Obtained with Loaded Processing Liquid

The two processing units of an Azura CX125 processor (Agfa) were filled with the processing liquid PL-1. Digitally exposed Aluva N plate precursors (Agfa) in a Luscher X POSE 230 UV setter were processed by feeding them through the filled Azura CX 125 processor at a processing speed of 1.4 m/min. The first 100 m² of Aluva N plate precursors were processed without adding starting processing liquid PL-1 to the processing units. At that point, the load of the processing liquid, expressed as the amount of m² of photosensitive layer dissolved per litre, amounts to 20m² / L as the content of the first processing unit tank is about 5 litres. Once that point reached, starting processing liquid PL-1 was added to the second processing unit in an amount of 50 ml /m² of processed plates (replenishment). When the tank of the second processing unit got filled up, excess of processing liquid then flowed into the tank of the first processing unit. When the tank of the first processing unit got filled up, excess of processing liquid then flowed into the drain. A total amount of plate precursors of 575 m² was processed without the need to clean processor parts or replace partially or fully the processing liquid in one of the processing units to avoid sludge, deposition of plate components or clogging of tubes and nozzles. At distinct points during the test, plates were put on the printing press as described in § 4 and the toning in the non-image areas of the prints was evaluated. The viscosity of the processing liquids in the 2 units was also monitored during the test. The results of liquid and plate measurements are summarized in Table 3.

TABLE 3

| Amount of | | | | | |
|---|---|---|---|---|---|
| processed plates | | | | | |
| (m²) | 0 | 20 | 100 | 250 | 350 |
| Viscosity of PL-1 | 1.9 | 1.9 | 2.1 | 18.5 | 2.3 |
| in 1^{st} unit (mPa.s) | | | | | |
| Viscosity of PL-1 | 1.9 | 1.9 | 2.0 | 2.0 | 1.9 |
| in 2^{nd} unit (mPa.s) | | | | | |
| Load of PL-1 in 1^{st} | 0 | 4 | 20 | 20 | 20 |
| unit (m²/L) | | | | | |
| Toning on the | No | No | No | No | No |
| press | | | | | |

As can be noticed from Table 3 no toning is observed in the non-image areas of the prints, even with printing plates obtained in a processing liquid which is loaded with a high amount of plate precursor components (up to 20 m²/L). It can also be seen that the viscosity, after a small increase during the start of the test, remains constant during the whole test.

From these results, the skilled in the art will appreciate that, when the production of printing plates according to the invention is done in a closed loop mode wherein the used processing liquid is collected in a tank and re-used again, 400m² of lithographic printing plate precursors comprising a diazonium compound can be processed, at least with one can of 20 L before this processing liquid will have to be replaced by a new one.

1-10. (canceled)

11. A method of making a lithographic printing plate, the method comprising:
image wise exposing a lithographic printing plate precursor with a digitally modulated light source to obtain image areas in exposed portions of the precursor and non-image areas in non-exposed portions of the precursor, the precursor including a hydrophilic substrate and a photosensitive layer including a diazonium compound on the hydrophilic substrate; and
contacting the precursor with an aqueous solution having a pH between 3 and 9 and including a water-soluble hydrophilic polymer and/or a surfactant so as to remove the photosensitive layer in the non-image areas and deposit the water-soluble hydrophilic polymer and/or the surfactant onto the substrate in the non-image areas of the precursor.

12. The method of making a lithographic printing plate according to claim 11, wherein the digitally modulated light source emits light having a wavelength between 360 nm and 420 nm.

13. The method of making a lithographic printing plate according to claim 11, wherein the aqueous solution includes a first surfactant selected from the group consisting of sodium, lithium, potassium, magnesium and calcium octyl, decyl and dodecyl sulfate, and a second anionic or non-ionic surfactant.

14. The method of making a lithographic printing plate according to claim 12, wherein the aqueous solution includes:
a first surfactant selected from the group consisting of a sodium octyl, decyl, or dodecyl sulfate; a lithium octyl, decyl, or dodecyl sulfate; a potassium octyl, decyl, or dodecyl sulfate; a magnesium octyl, decyl, or dodecyl sulfate; and a calcium octyl, decyl, or dodecyl sulfate; and
a second surfactant that is an anionic surfactant or a non-ionic surfactant.

15. The method of making a lithographic printing plate according to claim 13, wherein
when the second surfactant is the non-ionic surfactant, the non-ionic surfactant includes an aryl alkoxylate; and
when the second surfactant is the anionic surfactant, the anionic surfactant includes a salt of a sulfonic acid.

16. The method of making a lithographic printing plate according to claim 15, wherein the aqueous solution includes from 0.5% to 20% by weight of a water soluble organic solvent.

17. The method of making a lithographic printing plate according to claim 15, wherein
when the second surfactant is the non-ionic surfactant, an amount of the aryl alkoxylate is from 1% to 5% by weight with respect to a total weight of the aqueous solution; and
when the second surfactant is the anionic surfactant, an amount of the salt of the sulfonic acid is from 0.1% to 2.0% by weight with respect to a total weight of the aqueous solution.

18. The method of making a lithographic printing plate according to claim 16, wherein
when the second surfactant is the non-ionic surfactant, an amount of the aryl alkoxylate is from 1% to 5% by weight with respect to a total weight of the aqueous solution; and
when the second surfactant is the anionic surfactant, an amount of the salt of the sulfonic acid is from 0.1% to 2.0% by weight with respect to a total weight of the aqueous solution.

19. The method of making a lithographic printing plate according to claim 16, wherein the water soluble organic solvent includes an alcohol.

20. The method of making a lithographic printing plate according to claim 11, wherein the diazonium compound is a polycondensation product of 3-methoxy-4-diazo-diphenyl amine sulfate and 4,4′-bis-methoxy methyl-diphenyl ether.

21. The method of making a lithographic printing plate according to claim 11, wherein the photosensitive layer includes a binder, and a ratio by weight of the binder to the diazonium compound is 10 or less.

22. The method of making a lithographic printing plate according to claim 21, wherein the binder includes a half-ester obtained by reacting poly-(vinylbutyral-vinylalcohol-vinylacetate) with maleic acid anhydride.

23. The method of making a lithographic printing plate according claim 11, wherein the step of contacting is performed in a processing equipment including at least one processing unit.

24. The method of making a lithographic printing plate according claim 20, wherein the step of contacting is performed in a processing equipment including at least one processing unit.

25. The method of making a lithographic printing plate according to claim 24, wherein the step of contacting includes spraying the aqueous solution onto the precursor.

26. The method of making a lithographic printing plate according to claim 24, wherein the step of contacting includes contacting the precursor with rotating brushes.

27. The method of making a lithographic printing plate according to claim 25, wherein the step of contacting includes contacting the precursor with rotating brushes.

28. The method of making a lithographic printing plate according to claim 24, further comprising:
collecting and re-using the aqueous solution at least once after the step of contacting the precursor.

29. The method of making a lithographic printing plate according to claim 24, wherein the at least one processing unit includes a first processing unit and a second processing unit, and the step of contacting includes consecutively contacting the precursor with the aqueous solution in the first processing unit and the second processing unit.
